(19) United States
(12) Patent Application Publication
(10) Pub. No.: US 2024/0042573 A1
(43) Pub. Date: Feb. 8, 2024

(54) POLISHING PAD

(71) Applicant: DISCO CORPORATION, Tokyo (JP)

(72) Inventors: Norihisa ARIFUKU, Tokyo (JP); Takeshi SATO, Tokyo (JP)

(21) Appl. No.: 18/362,442

(22) Filed: Jul. 31, 2023

(30) Foreign Application Priority Data
Aug. 5, 2022 (JP) 2022-125831

(51) Int. Cl. B24B 37/24; B24B 57/02

(52) U.S. Cl. CPC B24B 37/245; B24B 57/02

(57) ABSTRACT

A polishing pad for polishing a silicon carbide substrate contains polyurethane and abrasive grains fixed by the polyurethane, and has a loss tangent (tan δ) represented by loss modulus (E″)/storage modulus (E′) of 0.1 to 0.35 at 30° C. and a glass transition temperature of 40° C. to 65° C. Also, a polishing method for polishing the silicon carbide substrate includes a holding step of holding a workpiece having the silicon carbide substrate by a chuck table and a polishing step of polishing the silicon carbide substrate by the polishing pad.

### BACKGROUND OF THE INVENTION

### Field of the Invention

The present invention relates to a polishing pad for polishing a silicon carbide substrate and a polishing method for polishing the silicon carbide substrate.

### Description of the Related Art

In recent years, attention has been paid to what is generally called a power semiconductor device that has high voltage resistance and is able to control a large current. The power semiconductor device is formed, for example, on one surface side of a silicon carbide (SiC) single crystal substrate better in electrical characteristics than a silicon (Si) single crystal substrate. It is known that, prior to formation of a power semiconductor device on one surface side of a silicon carbide single crystal substrate, the one surface side of the single crystal substrate is polished by chemical mechanical polishing (CMP) to be flattened (see, for example, Japanese Patent Laid-open No. 2012-253259). In Japanese Patent Laid-open No. 2012-253259, it is stated that the polishing rate of the silicon carbide single crystal substrate is enhanced by use of a polishing pad in which abrasive grains are fixed and acidic polishing liquid.

### SUMMARY OF THE INVENTION

However, a polishing pad in the related art has a problem that undulation is formed in a polished surface when formation of scratches due to polishing is restrained, and on the other hand, scratches are formed on the polished surface when the undulation is restrained.

The present invention has been made in consideration of the above-mentioned problem, and it is an object of the present invention to realize, at the time of polishing a silicon carbide single crystal substrate, both a reduction in the number of scratches on a polished surface and a reduction in the extent of undulation formed in the polished surface, while keeping a polishing rate of not less than a predetermined value.

In accordance with an aspect of the present invention, there is provided a polishing pad for polishing a silicon carbide substrate, the polishing pad containing polyurethane and abrasive grains fixed by the polyurethane, and the polishing pad having a loss tangent (tan δ) represented by loss modulus (E″)/storage modulus (E′) of 0.1 to 0.35 at 30° C. and a glass transition temperature of 40° C. to 65° C.

In accordance with another aspect of the present invention, there is provided a polishing method for polishing a silicon carbide substrate, including a holding step of holding a workpiece having the silicon carbide substrate by a chuck table of a polishing apparatus, and a polishing step of polishing the silicon carbide substrate by a disk-shaped polishing pad while supplying polishing liquid from a through-hole of a polishing tool that has a disk-shaped base substrate and the polishing pad and that is formed at a radially central part thereof with the through-hole penetrating the base substrate and the polishing pad, the polishing pad containing polyurethane and abrasive grains fixed by the polyurethane, and the polishing pad having a loss tangent (tan δ) represented by loss modulus (E″)/storage modulus (E′) of 0.1 to 0.35 at 30° C. and a glass transition temperature of 40° C. to 65° C.

When a silicon carbide substrate is polished by the polishing pad according to one mode of the present invention, both a reduction in the number of scratches on the polished surface and a reduction in the extent of undulation formed in the polished surface can be realized, while keeping a polishing rate of not less than a predetermined value.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a side view, partially in cross section, of a polishing apparatus;

FIG. 2 is a perspective view of a polishing tool;

FIG. 3A is an image of scratches on a polished surface in the case of polishing by a polishing pad;

FIG. 3B is an image of scratches on the polished surface in the case of polishing by another polishing pad;

FIG. 3C is an image of scratches on the polished surface in the case of polishing by a further polishing pad;

FIG. 4A is an image depicting an extent of undulation of the polished surface in the case of polishing by a polishing pad;

FIG. 4B is an image depicting the extent of undulation of the polished surface in the case of polishing by another polishing pad;

FIG. 4C is an image depicting the extent of undulation of the polished surface in the case of polishing by a further polishing pad;

FIG. 5 is a graph depicting a relation between temperature (axis of abscissas) and tan δ (axis of ordinates); and

FIG. 6 is a flow chart of a polishing method.

### DETAILED DESCRIPTION OF THE PREFERRED EMBODIMENT

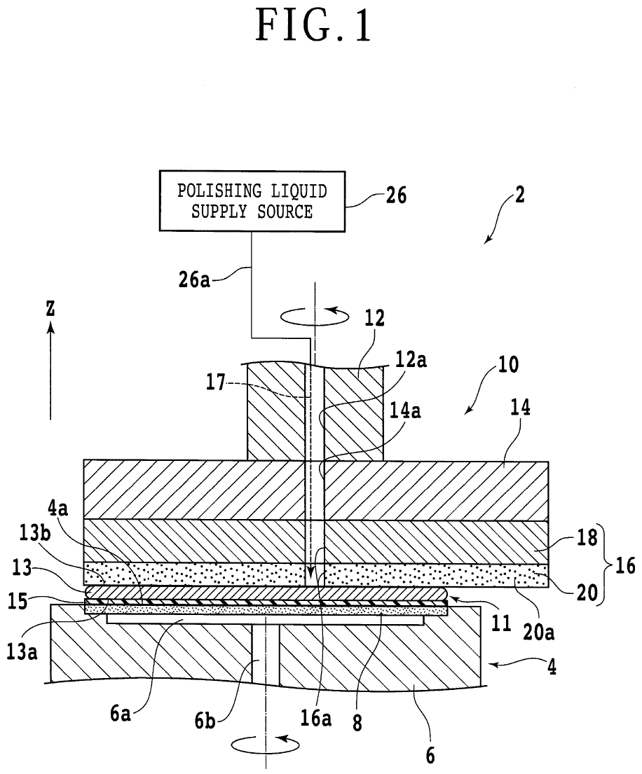

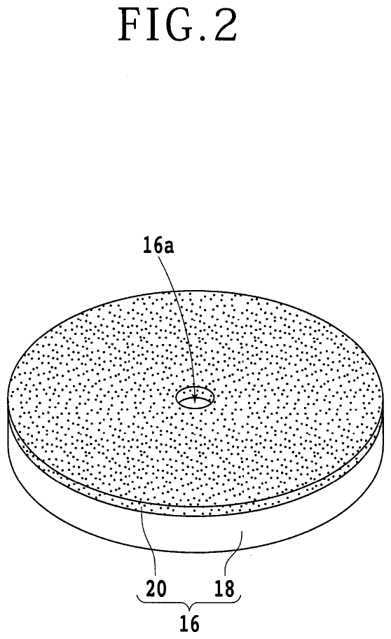

An embodiment according to one mode of the present invention will be described with reference to the attached drawings. FIG. 1 is a side view, partially in cross section, of a polishing apparatus 2. Note that a Z-axis direction indicated in FIG. 1 is substantially parallel to the vertical direction. FIG. 2 is a perspective view of a polishing tool 16, which will be described later, as viewed from a polishing pad 20 side.

The polishing apparatus 2 has a disk-shaped chuck table 4. To a lower surface side of the chuck table 4, a rotary shaft (not illustrated) whose longitudinal direction is aligned with the Z-axis direction is coupled. The rotary shaft is provided with a driven pulley (not illustrated). In the vicinity of the chuck table 4, a rotational drive source (not illustrated) such as a motor is provided. In addition, an output shaft of the rotational drive source is provided with a driving pulley (not illustrated). A toothed endless belt (not illustrated) is wrapped around the driving pulley and the driven pulley. When the rotational drive source is operated, rotation of the output shaft is transmitted to the rotary shaft of the chuck table 4, and the chuck table 4 is rotated around the rotary shaft.

The chuck table 4 has a nonporous disk-shaped frame body 6 formed from ceramics such as alumina. The frame body 6 is formed at an upper part thereof with a disk-shaped recess. A disk-shaped porous plate 8 formed from ceramics such as alumina is fixed in the recess. An upper surface of the porous plate 8 and an upper surface of the frame body 6 are substantially flush with each other to constitute a substantially flat holding surface 4a.

The porous plate 8 is connected to a suction source (not illustrated) such as a vacuum pump through flow channels 6a formed radially in a bottom surface of the recess of the frame body 6 and a flow channel 6b formed in such a manner as to penetrate the radial center of the bottom surface of the recess of the frame body 6. When the suction source is operated, a negative pressure is transmitted to the upper surface of the porous plate 8. A workpiece 11 is placed on the holding surface 4a. The workpiece 11 has a silicon carbide substrate 13 which is a disk-shaped single crystal substrate formed from silicon carbide. On one surface 13a side of the silicon carbide substrate 13, a plurality of planned division lines (not illustrated) are set in a grid pattern.

In each of rectangular regions partitioned by the plurality of planned division lines, a device (not illustrated) such as an insulated gate bipolar transistor (IGBT) or a metal-oxide-semiconductor field-effect transistor (MOSFET) is formed. To the one surface 13a side, a circular protective tape 15 formed from resin is stuck for preventing contamination of the silicon carbide substrate 13, shocks to the devices, and the like. Note that the number, kind, layout, and the like of the devices on the workpiece 11 are not limited to any particular number, kind, and the like. The workpiece 11 may not be provided with the devices. The one surface 13a side of the workpiece 11 is held under suction by the holding surface 4a with the protective tape 15 therebetween. In this instance, the other surface 13b of the silicon carbide substrate 13 is exposed upward. No device is formed on the other surface 13b side, and the other surface 13b is to be polished.

On the upper side of the holding surface 4a, a polishing unit 10 is disposed. The polishing unit 10 has a cylindrical spindle housing (not illustrated) whose longitudinal direction is disposed substantially in parallel to the Z-axis direction. To the spindle housing, a ball screw type Z-axis direction moving unit (not illustrated) is coupled. The Z-axis direction moving unit is, for example, a ball screw type moving mechanism for moving the polishing unit 10 along the Z-axis direction.

Part of a cylindrical spindle 12 whose longitudinal direction is disposed substantially in parallel to the Z-axis direction is rotatably accommodated in the spindle housing. The spindle 12 is provided at an upper-side part thereof with a rotational drive source (not illustrated) such as a motor for rotating the spindle 12. A lower end part of the spindle 12 projects downward to a position lower than a lower end part of the spindle housing. A central part of an upper surface of a disk-shaped mount 14 is coupled to the lower end part of the spindle 12. The mount 14 has a diameter larger than the diameter of the holding surface 4a.

To a lower surface of the mount 14, a disk-shaped polishing tool 16 which is substantially the same in diameter as the mount 14 is mounted by use of fixing members (not illustrated) such as bolts. The polishing tool 16 has a disk-shaped platen (base substrate) 18 coupled to the lower surface of the mount 14. The platen 18 is formed from hard resin. The platen 18 has substantially the same diameter as the mount 14. On a lower surface side of the platen 18, a disk-shaped polishing pad 20 substantially the same in diameter as the platen 18 is fixed with a double-faced adhesive tape (not illustrated) therebetween.

The polishing pad 20 has a main body section formed from hard foamed polyurethane. In the main body section, silica abrasive grains 20a are dispersed. In other words, the polishing pad 20 is what is generally called a fixed abrasive grain type polishing pad in which the abrasive grains 20a are fixed by the main body section. The polishing tool 16 is disposed coaxially with the spindle 12 and the mount 14. The polishing tool 16 is formed at a radially central part thereof with a through-hole 16a that penetrates the polishing pad 20 and the platen 18.

The through-hole 16a, a through-hole 12a penetrating a radially central part of the spindle 12, and a through-hole 14a penetrating a radially central part of the mount 14 constitute one flow channel. To an upper end part of the through-hole 12a, a polishing liquid supply source 26 is connected through a conduit 26a. The polishing liquid supply source 26 includes a storage tank (not illustrated) for storing polishing liquid 17 and a pump (not illustrated) for feeding the polishing liquid 17 from the storage tank into the conduit 26a. The polishing liquid 17 supplied from the polishing liquid supply source 26 is supplied through the through-holes 12a, 14a, and 16a to the polishing pad 20 and the workpiece 11 held under suction by the holding surface 4a.

The polishing liquid 17 is acidic liquid not containing the abrasive grains 20a. The polishing liquid 17 contains, for example, an aqueous solution in which permanganate and nitrate are dissolved. Examples of the permanganate to be used include sodium permanganate (NaMnO₄) and potassium permanganate (KMnO₄). Examples of the nitrate to be used include water-soluble compounds having nitric acid and transition metal elements, such as yttrium nitrate (Y(NO₃)₃), lanthanum nitrate (La(NO₃)₃), cerium nitrate (Ce(NO₃)₃), and zirconyl nitrate (also called zirconium oxynitrate) (ZrO(NO₃)₂). The polishing liquid 17 containing the aqueous solution in which the permanganate and the nitrate are dissolved is strongly acidic (for example, pH is a predetermined value less than 3). With the polishing liquid 17 thus strongly acidic, a high polishing rate can be realized as compared to the case where the polishing liquid 17 is weakly acidic (pH is a predetermined value not less than 3).

Next, based on experimental results, pad characteristics of the polishing pad and polishing characteristics when the polishing pad is used will be described. Five kinds of polishing pads P1 to P5 were produced, and for each of them, the polishing rate, the number of scratches on the polished surface, and the extent of undulation formed in the polished surface were evaluated (see Table 1 below). In producing each of the polishing pads P1 to P5, first, polyol A, polyol B, an isocyanate, and silica abrasive grains are blended in respective predetermined ratios (parts by mass), to produce a liquid resin mixture.

The polyol A used in the experiments was a polyoxyalkylene polyol having a hydroxyl value of 370 mg, the polyol B was a polyoxyalkylene polyol having a hydroxyl value of 172 mg, and the isocyanate was 4,4-diphenylmethane diisocyanate (MDI). However, in producing the polishing pad according to the present invention, the polyoxyalkylene polyol is not limitative; a vinyl polymer-containing polyoxyalkylene polyol, a polyester polyol, a polyoxyalkylene polyester block copolymer polyol, and the like can also be used as the polyol.

In addition, the isocyanate is not limited to the 4,4-diphenylmethane diisocyanate (MDI); other aromatic isocyanates, aliphatic isocyanates, alicyclic isocyanates, polymethylene polyphenyl polyisocyanates, and the like can also be used. In regard of the polyol, the amount of the polyol A was varied from 7.0 parts by mass to 59.0 parts by mass and the amount of the polyol B was varied from 41.0 parts by mass to 93.0 parts by mass such that the total amount of the polyol A and the polyol B was 100 parts by mass.

Further, based on 100 parts by mass of the total amount of the polyol A and the polyol B, the amount of the isocyanate was varied from 37 parts by mass to 81 parts by mass. In addition, based on 100 parts by mass of the total amount of the polyol A and the polyol B, the amount of the abrasive grains was varied from 110 parts by mass to 145 parts by mass. After five kinds of liquid resin mixtures each containing the abrasive grains mixed therein were prepared by thus varying the blending ratios, the liquid resin mixtures were poured into molds and left to stand at a room temperature of 20° C. to 30° C. for 24 hours, and were foamed and cured to produce foamed polyurethane polishing pads.

Thereafter, after each of the foamed polyurethane polishing pads was stuck to a lower surface side of the above-mentioned platen 18, the surface of the foamed polyurethane polishing pad was corrected by use of a correcting ring in which diamond abrasive grains were electroformed, to produce foamed polyurethane polishing pads (P1 to P5) of 2 mm in thickness in which a foamed structure was exposed to the surface.

A C-face (i.e., a carbon-terminated face) side of a silicon carbide substrate 13 (hereinafter, in the description concerning the experiments, a SiC wafer) which is a disk-shaped single crystal substrate formed of silicon carbide was directly held under suction by the holding surface 4a of the above-mentioned chuck table 4, and a Si-face (i.e., a silicon-terminated face) side of the SiC wafer was exposed upward. Next, while the chuck table 4 and the spindle 12 were rotated at predetermined rotating speeds and while the strongly acidic polishing liquid 17, in which the permanganate and the nitrate were dissolved, was supplied from the through-hole 16a of the polishing tool 16 to a position between the Si-face of the SiC wafer and the polishing pad 20, the polishing pad was pressed against the Si-face of the SiC wafer to polish the Si-face of the SiC wafer. The polishing conditions were set as follows:
Spindle rotating speed: 745 rpm
Chuck table rotating speed: 750 rpm
Polishing pressure: 40 kPa
Flow rate of polishing liquid: 200 ml/min
Diameter of polishing pad: φ450 mm
Diameter of SiC wafer: φ6 in (approximately 150 mm)

In regard of pad characteristics, specific gravity (g/cm³), glass transition temperature (° C.), and loss tangent (tan δ) at 30° C. were evaluated. Note that tan δ is calculated by dividing loss modulus (E″) by storage modulus (E′). In other words, tan δ=loss modulus (E″)/storage modulus (E′). For measurement of loss modulus (E″) and storage modulus (E′), an elasticity measuring system (EXSTAR DMS6100) made by Seiko Instruments Inc. was used.

By use of a compression test jig for the elasticity measuring system, while a cylindrical sample piece having a length of 2 mm and a diameter of 8 mm was subjected to a variation of temperature range from the room temperature to around 140° C. at a temperature rise rate of 2° C./min, measurement was conducted under the condition of a frequency of 2 Hz. In addition, the glass transition temperature (Tg) was made to be a peak temperature of tan δ in a graph with temperature on the axis of abscissas and tan δ on the axis of ordinates.

In regard of polishing characteristics, the polishing rate (μm/h) was measured, and the number of scratches and the extent of undulation were evaluated based on an image of the polished surface obtained after polishing. The number of scratches was evaluated by use of an optical testing system (Candela CS920) made and sold by KLA-Tencor Corporation. As a result of an image-based test, a polishing pad with few scratches was evaluated as A (good), and a polishing pad with many scratches was evaluated as B (bad). In regard of scratches, the polishing pads P1 to P4 were A, and the polishing pad P5 was B.

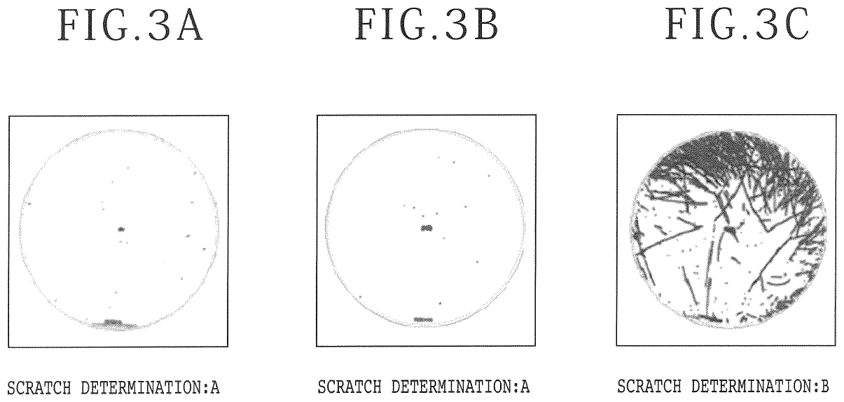

FIG. 3A is an image of scratches on the polished surface in the case of polishing by the polishing pad P1, FIG. 3B is an image of scratches on the polished surface in the case of polishing by the polishing pad P3, and FIG. 3C is an image of scratches on the polished surface in the case of polishing by the polishing pad P5. The extent of undulation was evaluated by use of a surface defect inspection system (YIS-300SP) made and sold by Yamashita Denso Corporation. Note that the surface defect inspection system is a system for inspecting with high sensitivity the surface state of a polished surface by application of the principle of what is called a magic mirror (in other words, a Chinese magic mirror). As a result of an image-based inspection, a polishing pad with a small extent of undulation was evaluated as A (good), and a polishing pad with a large extent of undulation was evaluated as B (bad). In regard of undulation, the polishing pad P1 was B, and the polishing pads P2 to P5 were A.

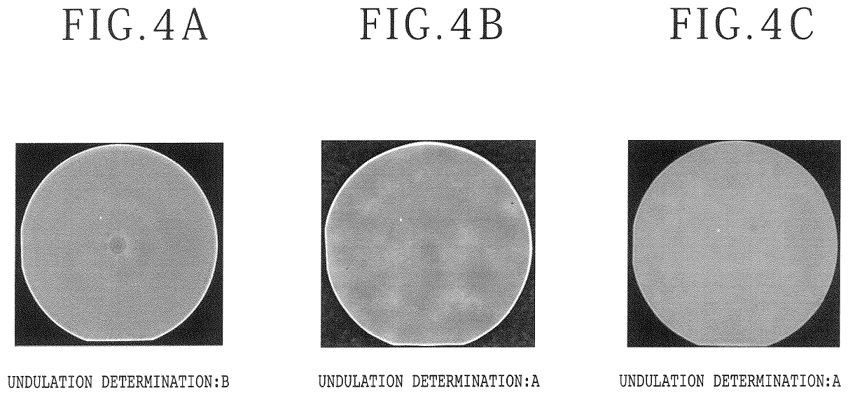

FIG. 4A is an image representing the extent of undulation of the polished surface in the case of polishing by the polishing pad P1, and radial lines appearing in FIG. 4A correspond to undulation formed in the polished surface. FIG. 4B is an image representing the extent of undulation of the polished surface in the case of polishing by the polishing pad P3, and FIG. 4C is an image representing the extent of undulation of the polished surface in the case of polishing by the polishing pad P5. In FIGS. 4B and 4C, there was no undulation like that in FIG. 4A. The contents concerning the above-mentioned experiments are collectively set forth in Table 1 below.

TABLE 1

| Polishing pad | P1 | P2 | P3 | P4 | P5 |
|---|---|---|---|---|---|
| Pad raw material | | | | | |
| Polyol A | 7.0 | 21.0 | 31.0 | 47.0 | 59.0 |
| Polyol B | 93.0 | 79.0 | 69.0 | 53.0 | 41.0 |
| Isocyanate | 37 | 58 | 64 | 72 | 81 |
| Silica abrasive grains | 110 | 126 | 131 | 138 | 145 |
| Pad characteristics | | | | | |
| Specific gravity (g/cm³) | 0.65 | 0.68 | 0.70 | 0.65 | 0.57 |
| Glass transition | 20 | 40 | 50 | 65 | 90 |
| temperature (° C.) | | | | | |
| tanδ (30° C.) | 0.40 | 0.16 | 0.20 | 0.12 | 0.04 |
| Polishing characteristics | | | | | |
| Polishing rate (μm/h) | 9.62 | 8.20 | 7.50 | 6.90 | 5.03 |
| Scratch | A | A | A | A | B |
| Undulation | B | A | A | A | A |
| Total | B | A | A | A | B |

As set forth in Table 1, in the total, a polishing pad with a polishing rate of not less than 6.00 (μm/h), with few scratches (that is, A), and with a small extent of undulation (that is, A) was evaluated as A (good), whereas a polishing pad with any one of the factors being unsatisfactory was evaluated as B (bad).

In the cases of the polishing pads P2, P3, and P4, the polishing rate was not less than 6.00 (μm/h), few scratches were observed, and the extent of undulation was small. Hence, the polishing pads P2, P3, and P4 are good polishing pads suitable for polishing the SiC wafer. In contrast, in the case of the polishing pad P1, though the polishing rate was not less than 6.00 (μm/h), the extent of undulation was large. Besides, in the case of the polishing pad P5, the polishing rate was less than 6.00 (μm/h) and, further, many scratches were observed. That means the polishing pads P1 and P5 are unsuitable for polishing the SiC wafer, as compared to the polishing pads P2, P3, and P4.

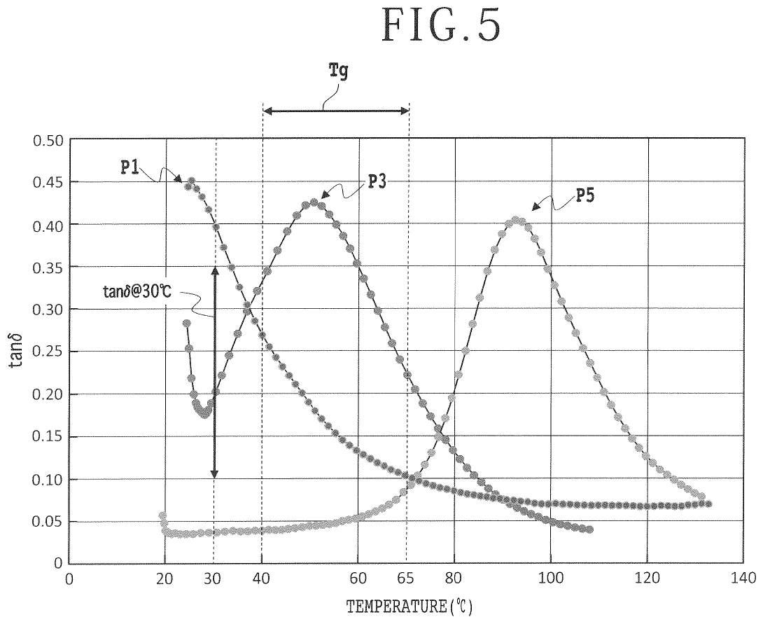

The suitableness for polishing the SiC wafer is represented in the glass transition temperature and tan δ at 30° C. of the pad characteristics. FIG. 5 is a graph depicting a relation between temperature (the axis of abscissas) and tan δ (the axis of ordinates), for the polishing pads P1, P3, and P5. In FIG. 5, a curve having a peak located on the leftmost side (low temperature side) is a temperature variation of tan δ of the polishing pad P1. In addition, in FIG. 5, a curve having a peak located in a central region (a range of 40° C. to 65° C.) is a temperature variation of tan δ of the polishing pad P3. Further, in FIG. 5, a curve having a peak located on the rightmost side (high temperature side) is a temperature variation of tan δ of the polishing pad P5.

Based on the experimental results set forth in Table 1 above, the glass transition temperature (Tg) is preferably 40° C. to 65° C. (see the range of Tg in FIG. 5). Similarly, based on the experimental results set forth in Table 1 above, the tan δ at 30° C. is preferably more than the tan δ at 30° C. of the polishing pad P5 but less than the tan δ at 30° C. of the polishing pad P1. Specifically, the tan δ at 30° C. is preferably more than 0.04 but less than 0.40, more preferably 0.1 to 0.35. Note that a range of 0.12 to 0.20 may also be adopted.

Here, the glass transition temperature and the tan δ at 30° C. will be discussed. First, an optimum temperature range for the glass transition temperature will be described. The hardness of the polishing pad can be adjusted by the hydroxyl value of the polyols and the blending amount of the isocyanate. By raising the hydroxyl value of the polyols and/or increasing the blending amount of the isocyanate, the glass transition temperature can be elevated. As the glass transition temperature is higher, the polishing pad is harder.

On the other hand, by lowering the hydroxyl value of the polyols and/or decreasing the blending amount of the isocyanate, the glass transition temperature can be lowered. As the glass transition temperature is lower, the polishing pad is softer. The hardness of the polishing pad influences the polishing rate, the number of scratches on the polished surface, and the extent of undulation of the polished surface. In polishing of the SiC wafer, as compared to polishing of a disk-shaped single crystal substrate formed of silicon (hereinafter, a Si wafer), a chemical reaction mainly occurs, and chemical mechanical polishing proceeds.

In the case of polishing a Si wafer, for example, a polishing pad having a glass transition temperature of 85° C. to 100° C. (in other words, being relatively hard) is used. However, in the case of polishing a SiC wafer, a polishing pad having a glass transition temperature of not more than 65° C. (in other words, being relatively soft) is preferably used, as clear from the experimental results set forth in Table 1. In short, in the case of polishing the SiC wafer, as compared to the case of polishing the Si wafer, the use of a polishing pad being relatively soft permits the polishing pad to make close contact with the polished surface, so that an enhanced polishing rate can be realized. Further, the number of scratches can be reduced.

However, when the polishing pad is too soft, the extent of undulation is enlarged, as verified by the experimental results of the polishing pad P1 set forth in Table 1 above. Hence, in the case of polishing the SiC wafer, the glass transition temperature is preferably not less than 40° C. In other words, the glass transition temperature is optimally 40° C. to 65° C.

Next, the significance of the tan δ at 30° C. will be described. As the value of the tan δ is smaller, the abrasive grains sink into the polishing pad with more difficulty, so that the number of scratches increases. On the other hand, as the value of the tan δ is larger, the abrasive grains sink into the polishing pad more easily, so that the number of scratches decreases. Incidentally, at the time of starting the polishing of the SiC wafer, the SiC wafer and the polishing pad are at substantially the same temperature as the room temperature (for example, 22° C. to 24° C.) of a clean room. As the polishing proceeds, the temperatures of the polished surface of the SiC wafer and the polishing surface of the polishing pad gradually rise to 30° C. and then to 40° C., but the temperature rise soon stops, and the temperatures become substantially constant on the order of 50° C.

Here, when it is difficult for the abrasive grains projecting from the polishing surface of the polishing pad to sink into the polishing pad at a timing near the start of polishing, it may cause formation of scratches on the polished surface. For example, in the case where the tan δ at 30° C. is less than 0.1 (for example, the polishing pad P5 in Table 1: 0.04), the abrasive grains projecting from the polishing surface may form scratches on the polished surface. On the other hand, in the case where the tan δ at 30° C. is in excess of 0.35 (for example, the polishing pad P1 in Table 1: 0.40), it is easy for the abrasive grains projecting from the polishing surface of the polishing pad to sink into the polishing pad, but in this case, the extent of undulation formed in the polished surface is enlarged. Hence, the tan δ at 30° C. is preferably 0.1 to 0.35.

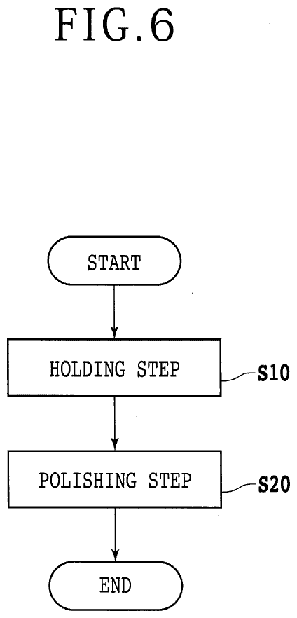

Next, a polishing method of polishing the silicon carbide substrate 13 of the workpiece 11 by use of the above-described polishing apparatus 2 will be described, with reference to FIG. 6. FIG. 6 is a flow chart of the polishing method. First, the workpiece 11 is held under suction by the holding surface 4a of the chuck table 4 (holding step S10). In the holding step S10, the workpiece 11 may be held under suction through the protective tape 15 in a state in which the protective tape 15 is stuck to the one surface 13a side of the workpiece 11, or the workpiece 11 may directly be held under suction by the holding surface 4a without the protective tape 15 being used.

Subsequently, while the chuck table 4 and the spindle 12 are rotated at respective predetermined rotating speeds and while the strongly acidic polishing liquid 17 is supplied from the through-hole 16a of the polishing tool 16, the polishing pad 20 is pressed against the other surface 13b side of the workpiece 11 at a predetermined pressure. As a result, the other surface 13b side of the silicon carbide substrate 13 is polished (polishing step S20). Note that the rotating speed of the chuck table 4 may be 400 rpm to 900 rpm, and more preferably, 500 rpm to 750 rpm. It is to be noted that the rotating speed of the spindle 12 is lower than the rotating speed of the chuck table 4 by a predetermined speed (for example, 5 rpm).

The polishing pressure may be 19 kPa to 60 kPa. A more preferable range is 29 kPa to 50 kPa. In addition, the flow rate of the polishing liquid 17 may be 50 ml/min to 300 ml/min. A more preferable range is 150 ml/min to 300 ml/min. When the silicon carbide substrate 13 is polished by use of the polishing pad 20 as described above, both a reduction in the number of scratches on the polished surface and a reduction in the extent of undulation formed in the polished surface can be realized, while keeping a polishing rate of not less than a predetermined value (for example, 6.00 μm/h).

Other than the above, the structures, methods, and the like concerning the above-described embodiment may appropriately be modified in carrying out the present invention insofar as the modifications do not depart from the scope of the object of the invention. A method for producing the silicon carbide substrate 13 is not limited to any particular method. The silicon carbide substrate 13 may be one sliced from an ingot or one peeled off from the ingot. Alternatively, the silicon carbide substrate 13 may be one formed on a seed crystal substrate by epitaxial growth.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing pad for polishing a silicon carbide substrate,
wherein the polishing pad contains polyurethane and abrasive grains fixed by the polyurethane, and has a loss tangent (tan δ) represented by loss modulus (E″)/storage modulus (E′) of 0.1 to 0.35 at 30° C. and a glass transition temperature of 40° C. to 65° C.

2. A polishing method for polishing a silicon carbide substrate, comprising:
a holding step of holding a workpiece having the silicon carbide substrate by a chuck table of a polishing apparatus; and
a polishing step of polishing the silicon carbide substrate by a disk-shaped polishing pad while supplying polishing liquid from a through-hole of a polishing tool that has a disk-shaped base substrate and the polishing pad and that is formed at a radially central part thereof with the through-hole penetrating the base substrate and the polishing pad, the polishing pad containing polyurethane and abrasive grains fixed by the polyurethane, and the polishing pad having a loss tangent (tan δ) represented by loss modulus (E″)/storage modulus (E′) of 0.1 to 0.35 at 30° C. and a glass transition temperature of 40° C. to 65° C.
